(19) United States
(12) Patent Application Publication
(10) Pub. No.: US 2024/0283220 A1
(43) Pub. Date: Aug. 22, 2024

(54) METHOD FOR MANUFACTURING PHOTONIC CRYSTAL AND METHOD FOR MANUFACTURING LIGHT-EMITTING DEVICE

(71) Applicant: SEIKO EPSON CORPORATION, Tokyo (JP)

(72) Inventors: Yoshitomo KUMAI, OKAYA-SHI (JP); Toru NIMURA, MATSUMOTO-SHI (JP)

(73) Assignee: SEIKO EPSON CORPORATION, Tokyo (JP)

(21) Appl. No.: 18/444,796

(22) Filed: Feb. 19, 2024

(30) Foreign Application Priority Data
Feb. 20, 2023 (JP) 2023-024237

(51) Int. Cl. H01S 5/18; C30B 25/02; C30B 29/40; C30B 29/42; C30B 29/68; H01S 5/343

(52) U.S. Cl. CPC H01S 5/18; C30B 25/02; C30B 29/40; C30B 29/42; C30B 29/68; H01S 5/34313

(57) ABSTRACT

A method for manufacturing a photonic crystal including forming a first layer, forming a first hole and a second hole, crystal-growing a second layer, to form, at the first hole, a first low refractive index portion, and form, at the second hole, a second low refractive index portion, wherein during formation of the first hole and the second hole, the first hole and the second hole are formed such that a diameter of the first hole is greater than a diameter of the second hole, and during formation of the first low refractive index portion and the second low refractive index portion, the second layer is crystal-grown such that a difference between the diameter of the first hole and a diameter of the first low refractive index portion is greater than a difference between the diameter of the second hole and a diameter of the second low refractive index portion.

The present application is based on, and claims priority from JP Application Serial Number 2023-024237, filed Feb. 20, 2023, the disclosure of which is hereby incorporated by reference herein in its entirety.

### BACKGROUND

### 1. Technical Field

The present disclosure relates to a method for manufacturing a photonic crystal and a method for manufacturing a light-emitting device.

### 2. Related Art

A photonic crystal that periodically changes in refractive index has been known.

For example, JP 2012-33706 A describes a method for manufacturing a two-dimensional photonic laser including a process of producing a base material layer, a process of periodically forming holes at the base material layer, and a process of producing a layer made of AlₓGa₁₋ₓAs at the base material layer and the holes by an epitaxial method.

In the method for manufacturing the two-dimensional photonic laser as described above, it is required to manufacture a photonic crystal capable of exhibiting a stable optical confinement effect.

### SUMMARY

One aspect of a method for manufacturing a photonic crystal according to the present disclosure includes
forming a first layer,
forming a first hole and a second hole at the first layer,
crystal-growing a second layer at the first hole and the second hole, to form, at the first hole, a first low refractive index portion having a refractive index lower than that of the first layer, and form, at the second hole, a second low refractive index portion having a refractive index lower than that of the first layer, wherein
during formation of the first hole and the second hole,
the first hole and the second hole are formed such that a diameter of the first hole is greater than a diameter of the second hole, and
during formation of the first low refractive index portion and the second low refractive index portion,
the second layer is crystal-grown such that a difference between the diameter of the first hole and a diameter of the first low refractive index portion is greater than a difference between the diameter of the second hole and a diameter of the second low refractive index portion.

An aspect of a method for manufacturing a light-emitting device according to the present disclosure includes
the one aspect of the method for manufacturing the photonic crystal.

### BRIEF DESCRIPTION OF THE DRAWINGS

FIG. 1 is a cross-sectional view schematically illustrating a light-emitting device according to the embodiment.

FIG. 2 is a flowchart for describing a method for manufacturing the light-emitting device according to the embodiment.

FIG. 3 is a cross-sectional view schematically illustrating a manufacturing process of the light-emitting device according to the embodiment.

FIG. 4 is a plan view schematically illustrating a manufacturing process of the light-emitting device according to the embodiment.

FIG. 5 is a cross-sectional view schematically illustrating a manufacturing process of the light-emitting device according to the embodiment.

FIG. 6 is a cross-sectional view schematically illustrating a manufacturing process of the light-emitting device according to the embodiment.

FIG. 7 is a cross-sectional view schematically illustrating a manufacturing process of the light-emitting device according to the embodiment.

FIG. 8 is a cross-sectional view schematically illustrating a manufacturing process of the light-emitting device according to the embodiment.

FIG. 9 is a cross-sectional view schematically illustrating a manufacturing process of the light-emitting device according to the embodiment.

FIG. 10 is a cross-sectional view schematically illustrating a manufacturing process of the light-emitting device according to the embodiment.

FIG. 11 is a cross-sectional view schematically illustrating a manufacturing process of the light-emitting device according to the embodiment.

FIG. 12 is a cross-sectional view schematically illustrating a manufacturing process of the light-emitting device according to the embodiment.

FIG. 13 is a cross-sectional view schematically illustrating a manufacturing process of the light-emitting device according to the embodiment.

FIG. 14 is a cross-sectional view schematically illustrating a manufacturing process of the light-emitting device according to the embodiment.

FIG. 15 is a cross-sectional view schematically illustrating a manufacturing process of the light-emitting device according to the embodiment.

FIG. 16 is a cross-sectional view schematically illustrating a manufacturing process of the light-emitting device according to the embodiment.

FIG. 17 shows HAADF-STEM and BF-STEM images of a first region.

FIG. 18 shows HAADF-STEM and BF-STEM images of a second region.

FIG. 19 shows HAADF-STEM and BF-STEM images of a third region.

FIG. 20 is a graph showing a relationship among diameter of a hole, period of the hole, diameter of a void, and thickness of an AlGaAs layer at a side surface of the hole.

### DESCRIPTION OF EMBODIMENTS

Preferred embodiments of the present disclosure will be described in detail below with reference to the drawings. Also, the embodiments described below do not unduly limit the content of the present disclosure described in the claims. In addition, not all the configurations described below are essential constituent elements of the present disclosure.

### 1. Light-Emitting Device

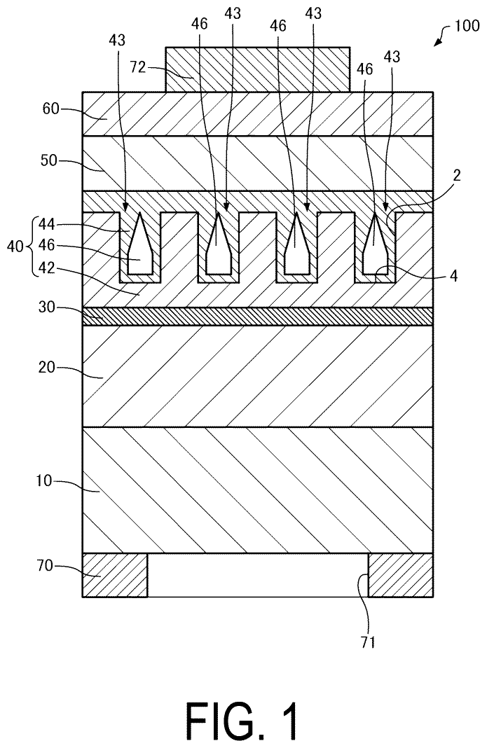

First, a light-emitting device according to the embodiment will be described with reference to the drawings. FIG. 1 is a cross-sectional view schematically illustrating a light-emitting device 100 according to the embodiment.

The light-emitting device 100 includes, for example, a substrate 10, a first semiconductor layer 20, a light-emitting layer 30, a photonic crystal 40, a second semiconductor layer 50, a contact layer 60, a first electrode 70, and a second electrode 72. The light-emitting device 100 is, for example, a photonic crystal surface emitting laser (PCSEL).

The substrate 10 is, for example, a GaAs substrate, or the like. The substrate 10 has, for example, conductivity. The substrate 10 is, for example, transmissive.

The first semiconductor layer 20 is provided at the substrate 10. The first semiconductor layer 20 is provided between the substrate 10 and the light-emitting layer 30. The first semiconductor layer 20 is, for example, an n-type AlGaAs layer doped with Si.

In the present specification, the description will be made in a way that, in a direction in which the first semiconductor layer 20 and the light-emitting layer 30 are stacked (simply referred to as a “stacking direction” below), when the light-emitting layer 30 is used as a reference, a direction from the light-emitting layer 30 toward the second semiconductor layer 50 is defined as “upward”, and a direction from the light-emitting layer 30 toward the first semiconductor layer 20 is defined as “downward”. In addition, a direction orthogonal to the stacking direction is also referred to as an “in-plane direction”.

The light-emitting layer 30 is provided at the first semiconductor layer 20. The light-emitting layer 30 is provided between the first semiconductor layer 20 and the second semiconductor layer 50. The light-emitting layer 30 is provided between the first semiconductor layer 20 and the photonic crystal 40. The light-emitting layer 30 generates light when an electric current is injected thereinto. The light-emitting layer 30 includes, for example, a well layer and a barrier layer. The well layer and the barrier layer are i-type semiconductor layers which are not doped with impurities intentionally. The well layer is an InGaAs layer, for example. The barrier layer is a GaAs layer, for example. The light-emitting layer 30 has a multiple quantum well (MQW) structure configured of the well layer and the barrier layer.

Also, the number of well layers and barrier layers forming the light-emitting layer 30 is not particularly limited. For example, only one well layer may be provided, and in this case, the light-emitting layer 30 has a SQW (Single Quantum Well) structure.

The photonic crystal 40 is provided at the light-emitting layer 30. The photonic crystal 40 is provided between the light-emitting layer 30 and the second semiconductor layer 50. A shape of the photonic crystal 40 is, for example, layered. The photonic crystal 40 includes a first layer 42, a second layer 44 and a low refractive index portion 46.

The first layer 42 is provided at the light-emitting layer 30. The first layer 42 is provided between the light-emitting layer 30 and the second layer 44. The first layer 42 is, for example, a C-doped p-type GaAs layer.

A plurality of holes 43 are formed at the first layer 42. A planar shape of the hole 43 is not particularly limited. A diameter of the hole 43 is, for example, from 10 nm to 500 nm, is desirably from 50 nm to 300 nm, and is more desirably from 100 nm to 200 nm. A depth of the hole 43 is, for example, from 100 nm to 500 nm, is desirably from 200 nm to 400 nm, is more desirably from 250 nm to 350 nm, and is further more desirably 300 nm. A maximum depth of the hole 43 is smaller than a maximum thickness of the first layer 42. The hole 43 does not reach the light-emitting layer 30.

Note that the “diameter of the hole 43” is a diameter when the planar shape of the hole 43 is a circle, and is a diameter of a minimum inclusion circle when the planar shape of the hole 43 is a shape other than the circle. For example, the diameter of the hole 43 is, when the planar shape of the hole 43 is a polygon, a diameter of a smallest circle that includes the polygon therein, and is, when the planar shape of the hole 43 is an ellipse, a diameter of a smallest circle that includes the ellipse therein. The same applies to a diameter of the low refractive index portion 46 described later.

At the first layer 42, unevenness is formed by the plurality of holes 43. The plurality of holes 43 are arrayed at a predetermined pitch in a predetermined direction when viewed from the stacking direction. In other words, the plurality of holes 43 are arrayed at a predetermined period in a predetermined direction when viewed from the stacking direction. The plurality of holes 43 are arrayed in, for example, a regular triangular lattice pattern or a square lattice pattern. The pitch of the plurality of holes 43 is, for example, from 10 nm to 500 nm, is desirably from 100 nm to 400 nm, and is more desirably from 200 nm to 300 nm.

Note that, the “pitch of the holes 43” is a distance between centers of the adjacent holes 43 in a predetermined direction. The “center of the hole 43” is, when the planar shape of the hole 43 is a circle, a center of the circle, and is, when the planar shape of the hole 43 is not a circle, a center of a minimum inclusion circle. For example, the center of the hole 43 is, when the planar shape of the hole 43 is a polygon, a center of a smallest circle including the polygon therein, and is, when the planar shape of the hole 43 is an ellipse, a center of a smallest circle including the ellipse therein.

The second layer 44 is provided at the first layer 42. The second layer 44 is provided between the first layer 42 and the second semiconductor layer 50. The second layer 44 is provided at upper surfaces of convex portions of the first layer 42 formed by the plurality of holes 43.

The second layer 44 is provided at the hole 43. The second layer 44 is provided at a side surface 2 and a bottom surface 4 of the hole 43. The side surface 2 and the bottom surface 4 are defined by the first layer 42. A portion provided at the side surface 2 of the second layer 44 includes a portion that gradually increases in thickness from the light-emitting layer 30 toward the second semiconductor layer 50. The portion that gradually increases in thickness is located at an upper portion of the hole 43. In the illustrated example, in a lower portion of the hole 43, portions of the second layer 44 provided at the side surface 2 and the bottom surface 4 are constant in thickness.

Note that although not illustrated, the second layers 44 may be provided at the plurality of holes 43 and need not be provided at the upper surfaces of the convex portions of the first layer 42. In this case, the second layers 44 provided at the plurality of holes 43 are separated from each other.

The second layer 44 is, for example, a group III-V semiconductor layer. The second layer 44 is, for example, a C-doped p-type AlGaAs layer. A composition ratio of Al and Ga in the second layer 44 is, for example, 1:1. For example, a refractive index of the first layer 42 and a refractive index of the second layer 44 are different from each other. The refractive index of the second layer 44 is, for example, lower than the refractive index of the first layer 42. Note that the second layer 44 may be a GaAs layer.

The low refractive index portion 46 is provided at the hole 43. A shape of the low refractive index portion 46 is defined by the second layer 44. The low refractive index portion 46 is a portion of the hole 43 that is not filled with the second layer 44. The low refractive index portion 46 includes a portion that gradually decreases in diameter from the light-emitting layer 30 toward the second semiconductor layer 50.

A refractive index of the low refractive index portion 46 is lower than the refractive index of the first layer 42 and the refractive index of the second layer 44. In the illustrated example, the low refractive index portion 46 is void. Note that although not illustrated, the low refractive index portion 46 need not be void and may be formed of a member having a refractive index lower than that of the first layer 42 and the second layer 44.

The second semiconductor layer 50 is provided at the photonic crystal 40. The second semiconductor layer 50 is provided at the second layer 44. The second semiconductor layer 50 is provided between the second layer 44 and the contact layer 60. The second semiconductor layer 50 is, for example, a C-doped p-type AlGaAs layer. The first semiconductor layer 20 and the second semiconductor layer 50 are clad layers having a function of confining light in the light-emitting layer 30. Note that the second semiconductor layer 50 may be provided continuously and integrally with the second layer 44.

In the light-emitting device 100, a pin diode is configured by the p-type second semiconductor layer 50, the first layer 42 and the second layer 44 of the p-type, the light-emitting layer 30 of an i-type, and the n-type first semiconductor layer 20. In the light-emitting device 100, when a forward bias voltage of the pin diode is applied between the first electrode 70 and the second electrode 72, an electric current is injected into the light-emitting layer 30 to cause recombination of electrons and holes in the light-emitting layer 30. This recombination causes light emission. The light generated in the light-emitting layer 30 propagates in the in-plane direction, forms a standing wave by an effect of the photonic crystal 40, and receives a gain in the light-emitting layer 30. Thus, laser is oscillated. Then, the light-emitting device 100 emits +1st order diffracted light and −1st order diffracted light as laser light in the stacking direction. Light directed to the second electrode 72 side is reflected by the second electrode 72. Thus, the light-emitting device 100 can emit light from the substrate 10 side.

Note that although not illustrated, a reflective layer may be provided between the second semiconductor layer 50 and the contact layer 60. The reflective layer is, for example, a distributed Bragg reflector (DBR) layer. The reflecting layer reflects light generated in the light-emitting layer 30 toward the substrate 10.

The contact layer 60 is provided at the second semiconductor layer 50. The contact layer 60 is provided between the second semiconductor layer 50 and the second electrode 72. A concentration of impurities of the contact layer 60 is higher than a concentration of impurities of the second semiconductor layer 50. The contact layer 60 is, for example, a C-doped p-type GaAs layer.

The first electrode 70 is provided under the substrate 10. The substrate 10 may be in ohmic contact with the first electrode 70. The first electrode 70 is electrically coupled to the first semiconductor layer 20 via the substrate 10. A material of the first electrode 70 is, for example, metal such as Au, Ge, or Ni, or an alloy thereof. The first electrode 70 is an electrode on one side for injecting an electric current into the light-emitting layer 30.

An opening portion 71 is formed at the first electrode 70. The opening portion 71 penetrates through the first electrode 70. As viewed in the stacking direction, the opening portion 71 overlaps the second electrode 72. Light generated in the light-emitting layer 30 is emitted through the opening portion 71.

The second electrode 72 is provided at the contact layer 60. The contact layer 60 may be in ohmic contact with the second electrode 72. The second electrode 72 is electrically coupled to the second semiconductor layer 50 through the contact layer 60. A planar shape of the second electrode 72 is, for example, a square. A material of the second electrode 72 is, for example, metal such as Au, Ge, or Ni, or an alloy thereof. The second electrode 72 is an electrode on another side for injecting an electric current into the light-emitting layer 30.

The light-emitting device 100 is, for example, applied to a laser processing device. Examples of such a laser processing device include a metal 3D printer in which a laser melting method (Selective Leaser Melting: SLM) is used, a laser cleaner that removes rust or the like on metal with laser light, a laser annealing device that heats a surface of metal or resin with laser light.

### 2. Method for Manufacturing Light-Emitting Device

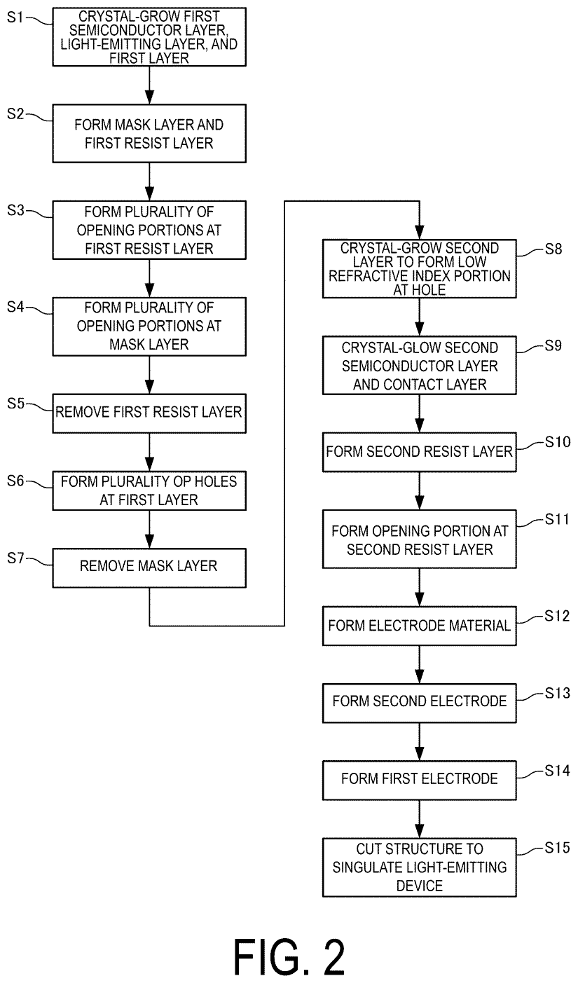

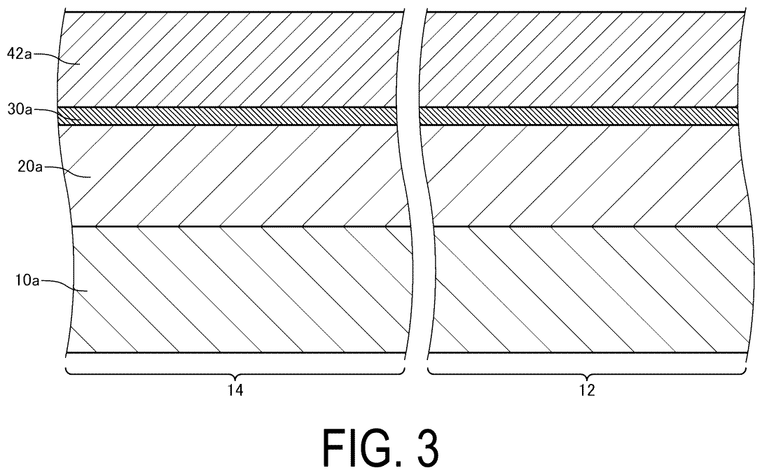

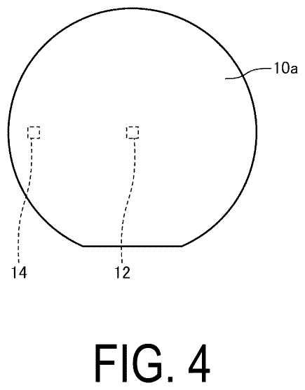

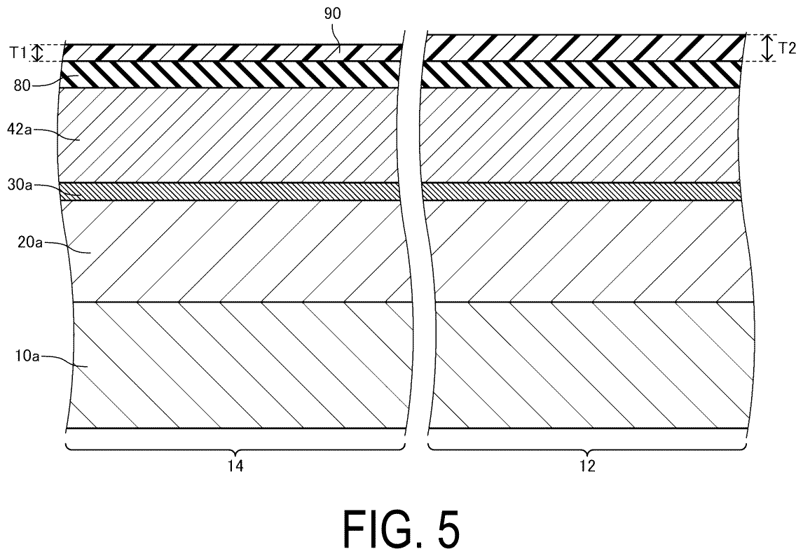

Next, a method for manufacturing the light-emitting device 100 according to the embodiment will be described with reference to the drawings. FIG. 2 is a flowchart for describing the method for manufacturing the light-emitting device 100 according to the embodiment. FIG. 3 is a cross-sectional view schematically illustrating a manufacturing process of the light-emitting device 100 according to the embodiment. FIG. 4 is a plan view schematically illustrating a manufacturing process of the light-emitting device 100 according to the embodiment. FIGS. 5 to 16 are each a cross-sectional view schematically illustrating a manufacturing process of the light-emitting device 100 according to the embodiment.

As illustrated in FIGS. 2 and 3, a first semiconductor layer 20a, a light-emitting layer 30a, and the first semiconductor layer 42 are epitaxially grown at the substrate 10a in this order (step S1). Specifically, the first semiconductor layer 20a, the light-emitting layer 30a, and a first layer 42a are epitaxially grown by an MOCVD (Metal Organic Chemical Vapor Deposition) method.

The substrate 10a, the first semiconductor layer 20a, the light-emitting layer 30a, and the first layer 42 are cut in step S15 described later to become the substrate 10, the first semiconductor layer 20, the light-emitting layer 30, and the first layer 42 illustrated in FIG. 1, respectively.

The substrate 10a is, for example, a wafer as illustrated in FIG. 4. The substrate 10a includes a central portion 12 including a center and a peripheral portion 14 located at a periphery when viewed from the stacking direction. The central portion 12 and the peripheral portion 14 are spaced apart from each other. A distance between the central portion 12 and the peripheral portion 14 is, for example, greater than one third of a diameter of the wafer. In each of FIGS. 3 and 5 to 16, the central portion 12 and the peripheral portion 14 of the substrate 10a are illustrated.

As illustrated in FIG. 5, a mask layer 80 is formed at the first layer 42a, and a first resist layer 90 is formed at the mask layer 80 (step S2). The mask layer 80 is formed by a plasma CVD (Chemical Vapor Deposition) method, for example. The mask layer 80 is a silicon nitride layer, for example. The first resist layer 90 is formed by, for example, a spin coating method.

In the substrate 10a, for example, warpage occurs due to heat in the process (step S1) of crystal-growing the first semiconductor layer 20a, the light-emitting layer 30a, and the first layer 42a. Therefore, for example, as illustrated in FIG. 5, a thickness T1 of the first resist layer 90 at the peripheral portion 14 is smaller than a thickness T2 of the first resist layer 90 at the central portion 12.

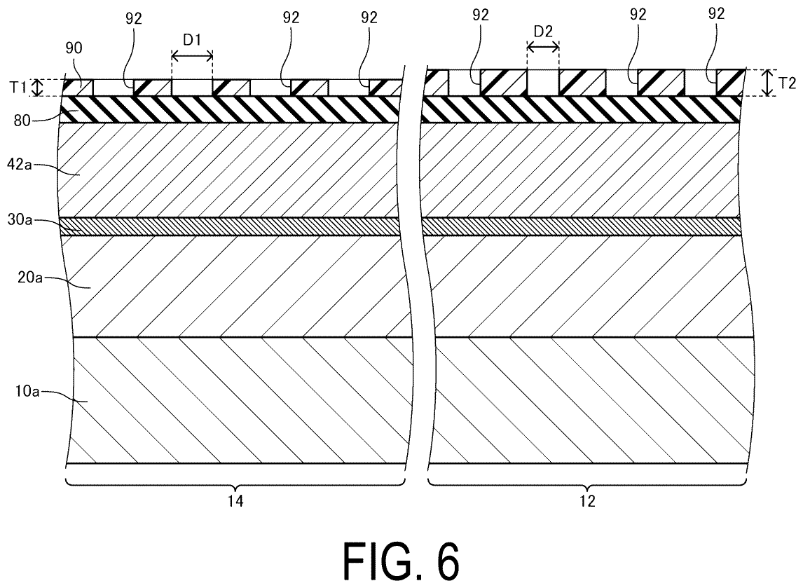

As illustrated in FIG. 6, a plurality of opening portions 92 are formed at the first resist layer 90 (step S3). The opening portion 92 is formed by exposure and development. The exposure may be performed using an electron beam drawing apparatus. The opening portion 92 penetrates through the first resist layer 90. Since the thickness T1 of the first resist layer 90 at the peripheral portion 14 is smaller than the thickness T2 of the first resist layer 90 at the central portion 12, a diameter D1 of the opening portion 92 at the peripheral portion 14 is greater than a diameter D2 of the opening portion 92 at the central portion 12. Note that the present disclosure is not limited thereto, and the opening portion 92 may be formed by a nanoimprint method.

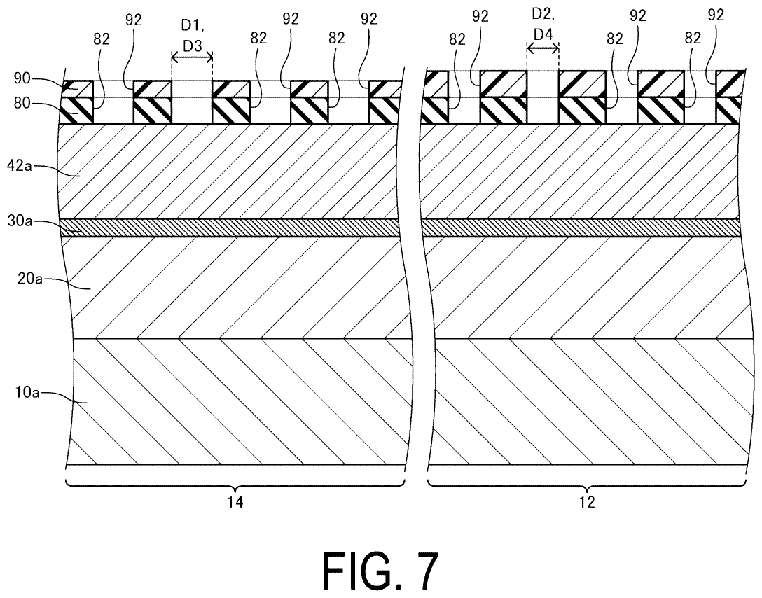

As illustrated in FIG. 7, the mask layer 80 is etched using the first resist layer 90 as a mask to form a plurality of opening portions 82 at the mask layer 80 (step S4). The etching is, for example, dry etching using a fluorine-based gas. The opening portion 82 penetrates through the mask layer 80. Since the diameter D1 of the opening portion 92 at the peripheral portion 14 is greater than the diameter D2 of the opening portion 92 at the central portion 12, a diameter D3 of the opening portion 82 at the peripheral portion 14 is greater than a diameter D4 of the opening portion 82 at the central portion 12. In the illustrated example, the diameters D1 and D3 are equal to each other. The diameters D2 and D4 are equal to each other.

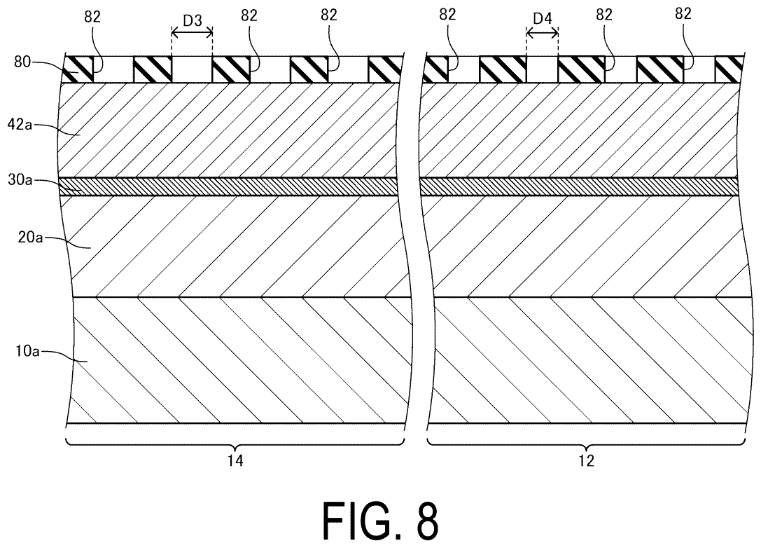

The first resist layer 90 is removed as illustrated in FIG. 8 (step S5). The removal of the first resist layer 90 is performed by ashing, for example.

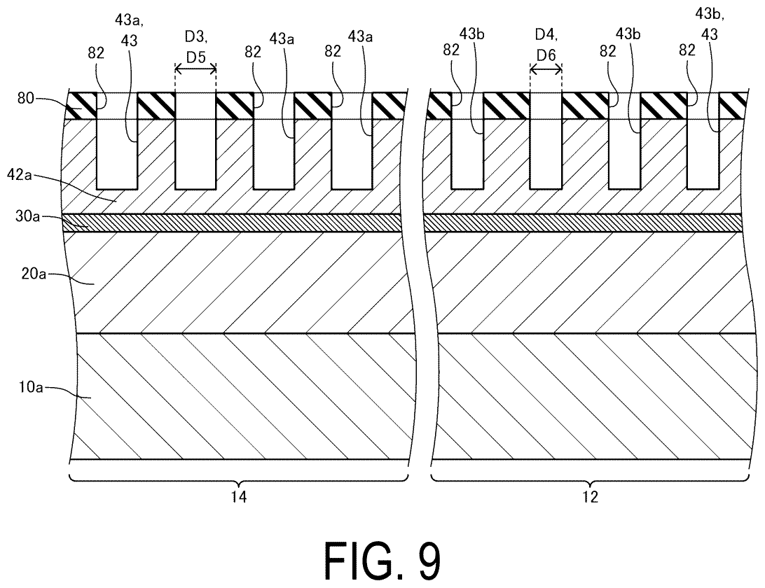

As illustrated in FIG. 9, the first layer 42a is etched using the mask layer 80 as a mask to form a plurality of the holes 43 at the first layer 42a (step S6). The etching is, for example, dry etching using a chlorine-based gas. In this process, holes 43a and 43b are formed such that a diameter D5 of the hole 43a at the peripheral portion 14 is greater than a diameter D6 of the hole 43b at the central portion 12. Since the diameter D3 of the opening portion 82 at the peripheral portion 14 is greater than the diameter D4 of the opening portion 82 at the central portion 12, the diameter D5 of the hole 43a at the peripheral portion 14 is greater than the diameter D6 of the hole 43b at the central portion 12. In the illustrated example, the diameters D3 and D5 are equal to each other. The diameters D4 and D6 are equal to each other. Among the plurality of holes 43, the hole 43a is the hole 43 provided at the peripheral portion 14. Among the plurality of holes 43, the hole 43b is the hole 43 provided at the central portion 12.

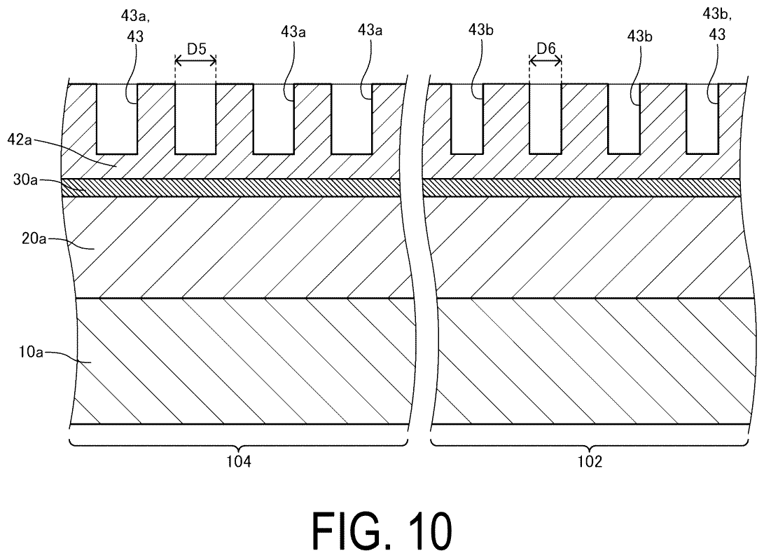

As illustrated in FIG. 10, the mask layer 80 is removed (step S7). The removal of the mask layer 80 is performed by, for example, wet etching. Next, a surface of the first layer 42a is cleaned by thermal cleaning or the like.

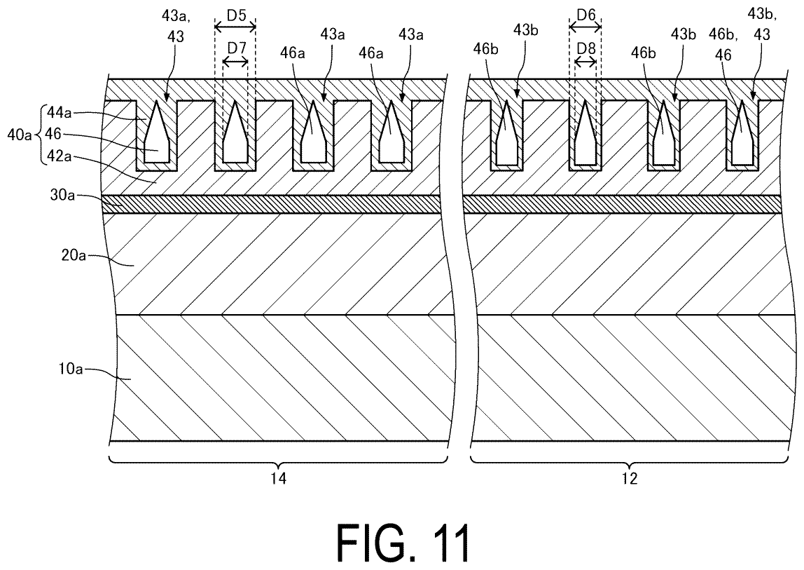

As illustrated in FIG. 11, the second layer 44a is crystal-grown at the hole 43 to form the low refractive index portion 46 at the hole 43 (step S8). Concretely, the second layer 44a is epitaxially grown by the MOCVD method. The second layer 44a is formed at the first layer 42a. By this process, a photonic crystal 40a is formed. The second layer 44a and the photonic crystal 40a are cut in step S15 described later to become the second layer 44 and the photonic crystal 40 illustrated in FIG. 1, respectively.

A growth temperature of the second layer 44a is, for example, from 550° C. to 650° C., desirably from 570° C. to 640° C., and more desirably from 600° C. to 625° C. In the crystal-growth of the second layer 44a, a first gas for supplying a group III element and a second gas for supplying a group V element are used. The first gas contains, for example, trimethyl gallium (TMG) which is a raw material of Ga and trimethyl aluminum (TMA) which is a raw material of Al. The second gas contains, for example, tert-butylarsine (TBA) which is a raw material of As. A ratio of a flow rate of the second gas to a flow rate of the first gas is, for example, from 10 to 30, is desirably from 15 to 25, and is more desirably from 17 to 23.

In this process, flow rates of the first gas and the second gas supplied to the hole 43 are lower than flow rates of the first gas and the second gas supplied to an upside of the hole 43. Therefore, a lateral growth speed of the second layer 44a at the hole 43 is lower than a lateral growth speed of the second layer 44a at the upside of the hole 43. Therefore, the upside of the hole 43 is closed earlier by the second layer 44a. Accordingly, the hole 43 is no more supplied with the first gas and the second gas. As a result, the low refractive index portion 46 which is void is formed.

In this process, the second layer 44a is crystal-grown so that a difference between a diameter D7 of the low refractive index portion 46a at the peripheral portion 14 and the diameter D5 of the hole 43a at the peripheral portion 14 is greater than a difference between a diameter D8 of the low refractive index portion 46b at the central portion 12 and the diameter D6 of the hole 43b at the central portion 12. In the example illustrated, the diameter D5 is a maximum width of the hole 43a. The diameter D6 is a maximum width of the hole 43b. The diameter D7 is a maximum width of the low refractive index portion 46a. The diameter D7 is smaller than the diameter D5. The diameter D8 is a maximum width of the low refractive index portion 46b. The diameter D8 is smaller than the diameter D6. Among a plurality of the low refractive index portions 46, the low refractive index portion 46a is the low refractive index portion 46 provided at the peripheral portion 14. Among the plurality of low refractive index portions 46, the low refractive index portion 46b is the low refractive index portion 46 provided at the central portion 12.

In this process, an upside of the hole 43a at the peripheral portion 14 is closed by the second layer 44a later than an upside of the hole 43b at the central portion 12. That is, at the time point when the upside of the hole 43b is closed by the second layer 44a, the upside of the hole 43a is not yet closed by the second layer 44a. Therefore, the more first gas and second gas are supplied to the hole 43a as compared to the hole 43b. As described above, the difference between the diameter D7 and the diameter D5 can be made greater than the difference between the diameter D8 and the diameter D6 by exhibiting a shadow effect in which a larger amount of gas is supplied to the hole 43 having a larger diameter. Note that the diameters D1 to D8 are measured by, for example, a transmission electron microscope (TEM) or a scanning electron microscope (SEM).

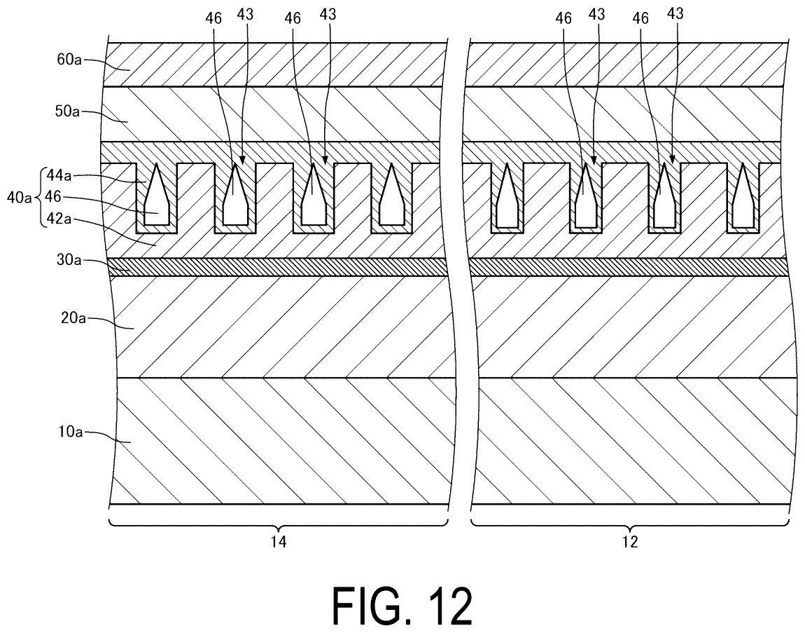

As illustrated in FIG. 12, a second semiconductor layer 50a and a contact layer 60a are crystal-grown in this order at the second layer 44a (step S9). To be specific, the second semiconductor layer 50a and the contact layer 60a are epitaxially grown by the MOCVD method. The second semiconductor layer 50a and the contact layer 60a are cut in step S15 described later to become the second semiconductor layer 50 and the contact layer 60 illustrated in FIG. 1, respectively.

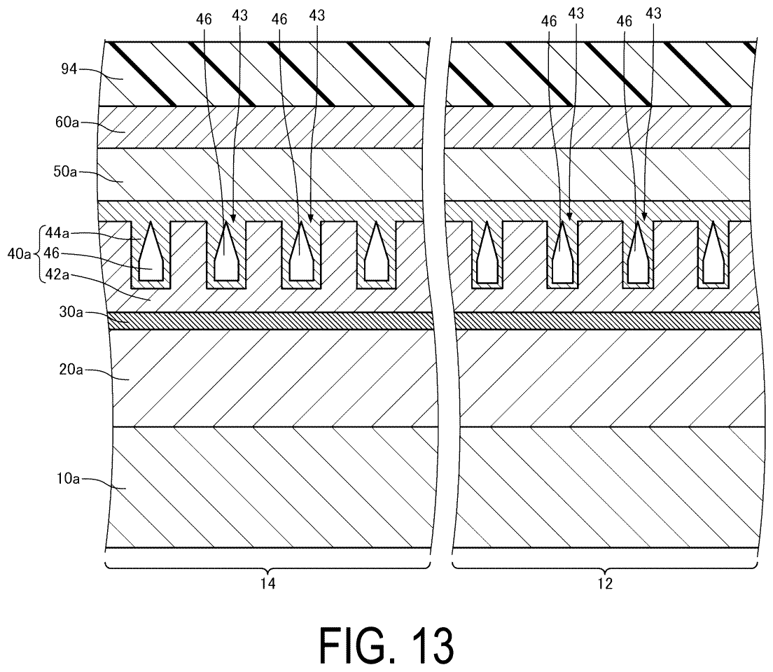

As illustrated in FIG. 13, a second resist layer 94 is formed at the contact layer 60a (step S10). The second resist layer 94 is formed by, for example, a spin coating method. Although not illustrated, a thickness of the second resist layer 94 at the peripheral portion 14 may be smaller than a thickness of the second resist layer 94 at the central portion 12.

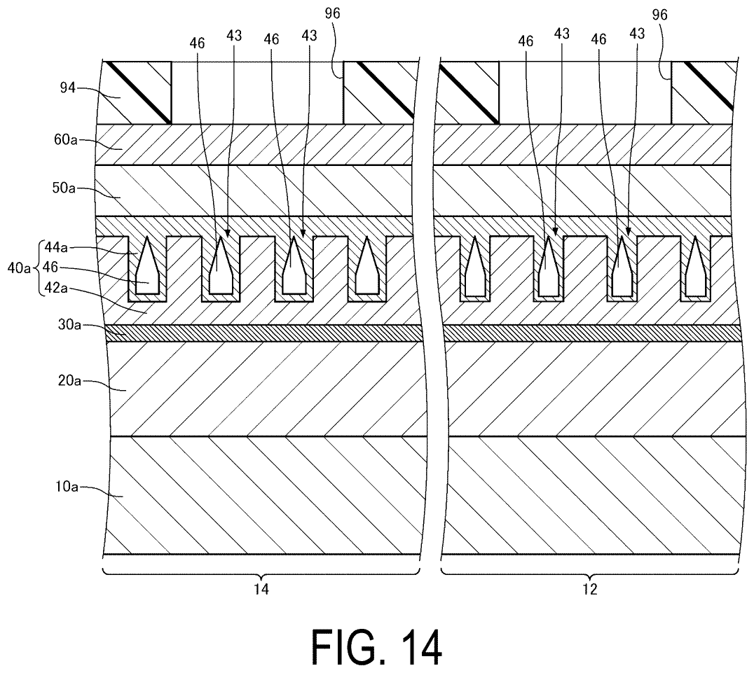

As illustrated in FIG. 14, an opening portion 96 is formed at the second resist layer 94 (step S11). The opening portion 96 is formed by exposure and development. The exposure may be performed using an electron beam drawing apparatus. The opening portion 96 penetrates through the second resist layer 94.

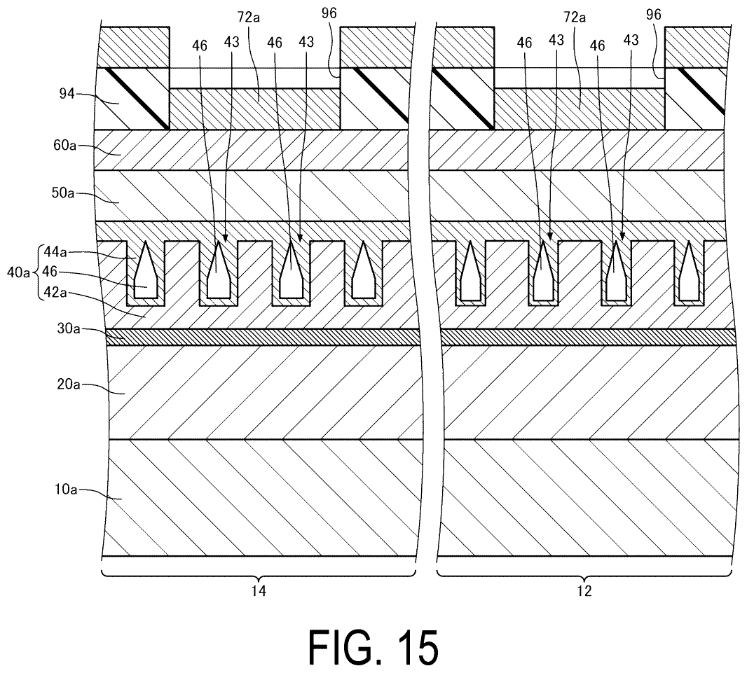

As illustrated in FIG. 15, an electrode material 72a to be the second electrodes 72 is formed at the contact layer 60a and the second resist layer 94 (step S12). The electrode material 72a is formed by, for example, a vacuum deposition method or a sputtering method.

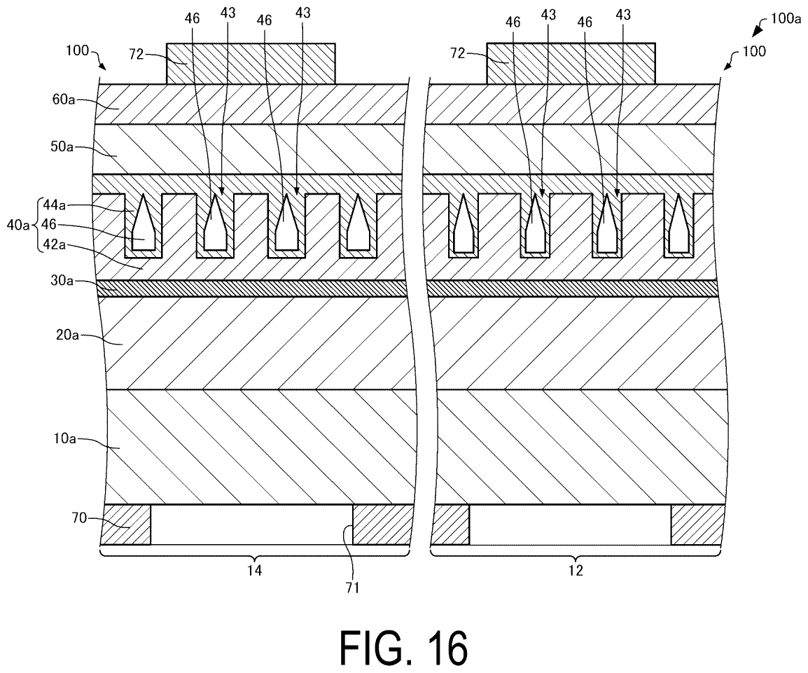

As illustrated in FIG. 16, the second resist layer 94 is removed, and the second electrode 72 is formed by a lift-off method (step S13).

Next, the first electrode 70 is formed under the substrate 10 (step S14). The first electrode 70 is formed by, for example, a vacuum deposition method after mirror-polishing a lower surface of the substrate 10. Subsequently, the first electrode 70 is patterned to form the opening portion 71. The patterning is performed by photolithography and etching, for example.

A structure 100a including a plurality of the light-emitting devices 100 can be manufactured through the above processes.

Next, the structure 100a is cut to singulate the light-emitting device 100 (step S15). Examples of a cutting method include blade dicing and laser dicing.

The light-emitting device 100 illustrated in FIG. 1 can be manufactured through the above processes.

### 3. Actions and Effects

A method for manufacturing the photonic crystal 40a includes a process of forming the first layer 42a, and a process of forming the hole 43a at the peripheral portion 14 as a first hole and the hole 43b at the central portion 12 as a second hole at the first layer 42a. Furthermore, the method for manufacturing the photonic crystal 40a includes a process of crystal-growing the second layer 44a at the hole 43a and the hole 43b to form the low refractive index portion 46a as a first low refractive index portion having a refractive index lower than that of the first layer 42a at the hole 43a, and to form the low refractive-index portion 46b as a second low refractive index portion having a refractive index lower than that of the first layer 42a at the hole 43b. In the process of forming the holes 43a and 43b, the holes 43a and 43b are formed so that the diameter D5 of the hole 43a is greater than the diameter D6 of the hole 43b. In the process of forming the low refractive index portions 46a and 46b, the low refractive index portions 46a and 46b are formed so that a difference between the diameter D5 of the hole 43a and the diameter D7 of the low refractive index portion 46a is greater than a difference between the diameter D6 of the hole 43b and the diameter D8 of the low refractive index portion 46b.

Therefore, in the method for manufacturing the photonic crystal 40a, a difference between the diameter D7 of the low refractive index portion 46a and the diameter D8 of the low refractive index portion 46b can be made smaller as compared to a case where the difference between the diameter D7 and the diameter D5 is the same as the difference between the diameter D8 and the diameter D6 in the crystal growth of the second layer, for example. Accordingly, variations in an optical confinement coefficient can be reduced. Therefore, it is possible to manufacture the photonic crystal 40a capable of exhibiting a stable optical confinement effect.

In the method for manufacturing the photonic crystal 40a, a refractive index of the first layer 42a and a refractive index of the second layer 44a are different from each other. Therefore, in the method for manufacturing the photonic crystal 40a, it is easy to adjust a refractive index of the photonic crystal 40a.

In the method for manufacturing the photonic crystal 40a, the second layer 44a is crystal-grown by the MOCVD method. Therefore, in the method for manufacturing the photonic crystal 40a, the shadow effect can be exhibited during the crystal growth of the second layer 44a.

In the method for manufacturing the photonic crystal 40a, the growth temperature of the second layer 44a is from 550° C. to 650° C. Therefore, in the method for manufacturing the photonic crystal 40a, the shadow effect can be exhibited during the crystal growth of the second layer 44a. Furthermore, since the growth temperature of the second layer 44a is equal to or greater than 550° C., crystal defects are less likely to occur in the second layer 44a. Further, since the growth temperature of the second layer 44a is equal to or less than 650° C., the shapes of the holes 43a and 43b are unlikely to be deformed due to heat.

In the method for manufacturing the photonic crystal 40a, the second layer 44a is the group III-V semiconductor layer, and the ratio of the flow rate of the second gas for supplying the group V element to the flow rate of the first gas for supplying the group III element is from 10 to 30 in the crystal growing of the second layer 44a, therefore, in the method for manufacturing the photonic crystal 40a, the shadow effect can be exhibited in the crystal growing of the second layer 44a.

In the method for manufacturing a photonic crystal 40a, the low refractive index portions 46a and 46b are void. Therefore, in the method for manufacturing the photonic crystal 40a, the refractive indices of the low refractive index portions 46a and 46b can be reduced.

In the method for manufacturing the photonic crystal 40a, in the crystal growth of the second layer 44a, the upside of the holes 43a and 43b is closed by the second layer 44a, so that the first gas and the second gas are no more supplied to the holes 43a and 43b to form a void, and the upside of the hole 43a is closed later than the upside of the hole 43b. Therefore, in the method for manufacturing the photonic crystal 40, the difference between the diameter D7 and the diameter D5 can be made greater than the difference between the diameter D8 and the diameter D6.

The method for manufacturing the light-emitting device 100 includes the method for manufacturing the photonic crystal 40a. As described above, in the method for manufacturing the photonic crystal 40a, the variations in the optical confinement factor can be reduced. As indicated Formula (1) described below, an optical confinement factor Γ affects a threshold current density Jₜₕ. Therefore, in the method for manufacturing the light-emitting device 100, variations in the threshold current density Jₜₕ can be reduced.

$$\begin{matrix}[ Formula 1 ] & \\ {J}_{th} = \frac{{J}_{0} d}{{η}_{spon}} + \frac{{J}_{0} d}{{g}_{0} {η}_{spon} Γ} ( {α}_{int} + {α}_{//} + ( 1 + \sqrt{R} cos θ ) ( {α}_{⊥} ) & ( 1 )\end{matrix}$$

$$g = \frac{{g}_{0}}{{J}_{0}} ( {J}_{nom} - {J}_{0} ) \qquad ( 2 )$$

In Formula (1), Jo and go are fixed values. ηₛₚₒₙ is an internal quantum efficiency during spontaneous emission. d is a thickness of the light-emitting layer 30. αᵢₙₜ is an internal loss. α_{//} is an in-plane loss. α_{⊥} is a radiative loss. R is a power reflectivity. Θ is a phase shift. g is a gain, and is expressed by Formula (2) described above. In Formula (2), Jₙₒₘ is a normalized current density.

Note that although the example in which the first hole is the hole 43a at the peripheral portion 14 and the second hole is the hole 43b at the central portion 12 has been described above, the positions of the first hole and the second hole in plan view are not particularly limited as long as the diameter of the first hole is greater than the diameter of the second hole.

Additionally, although the example in which the diameters of the first hole and the second hole result from the thickness of the first resist layer 90 has been described above, the diameters of the first hole and the second hole may result from other conditions instead of the thickness of the first resist layer 90 as long as the diameter of the first hole is greater than the diameter of the second hole.

### 4. Experimental Example

### 4.1. Sample Preparation

A GaAs layer was crystal-grown at a GaAs substrate by an MOCVD method. Next, a SiN layer was formed at the GaAs layer by a plasma CVD method. Next, a resist layer was formed at the SiN layer by a spin coating method. Next, the resist layer was exposed by an electron beam drawing apparatus and was further developed. Next, the SiN layer was dry-etched with a fluorine-based gas using the resist layer as a mask. Next, the resist layer was removed by ashing. Next, by using the SiN layer as a mask, the GaAs layer was dry-etched with a chlorine-based gas to form a plurality of holes at the GaAs layer. Next, the SiN layer was removed by wet etching. Next, a surface of the GaAs layer was cleaned by thermal cleaning.

Next, an AlGaAs layer was crystal-grown at the GaAs layer by the MOCVD method. A growth temperature of the AlGaAs layer was 600° C. In crystal growth of the AlGaAs layer, a first gas containing TMG and TMA and a second gas containing TBA were used. A flow rate of the second gas to a flow rate of the first gas was 20. The crystal growth of the AlGaAs layer was performed so that a composition ratio of Al and Ga was 1:1.

Through the above processes, a sample was prepared.

### 4.2. Cross-Section Observation

The above sample was processed with a focused ion beam (FIB) processing apparatus, and then a cross section thereof was observed with a scanning transmission electron microscope (STEM). As the FIB processing apparatus, “Helios” manufactured by FEI Company Japan Ltd. was used. A dose amount of the FIB processing apparatus was 0.7 μs. “Talos” manufactured by Thermo Scientific was used as the STEM. An accelerating voltage of the STEM was 200 kV.

The cross-sectional observation was performed on three regions of the sample, that is, a first region, a second region, and a third region. The first region, the second region, and the third region are regions at different positions in plan view.

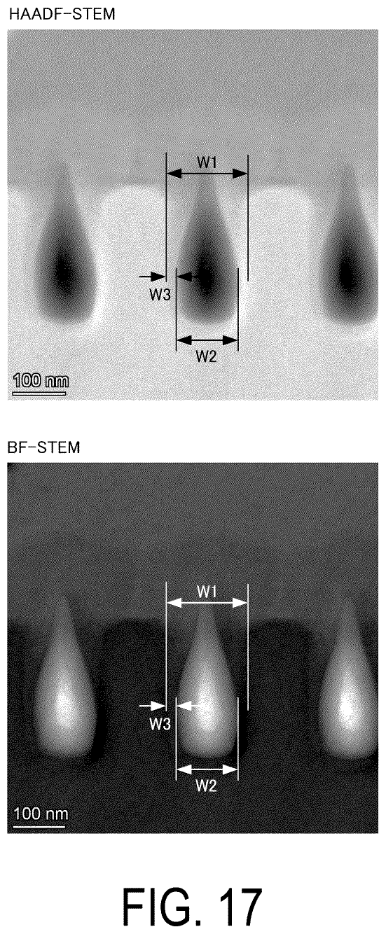

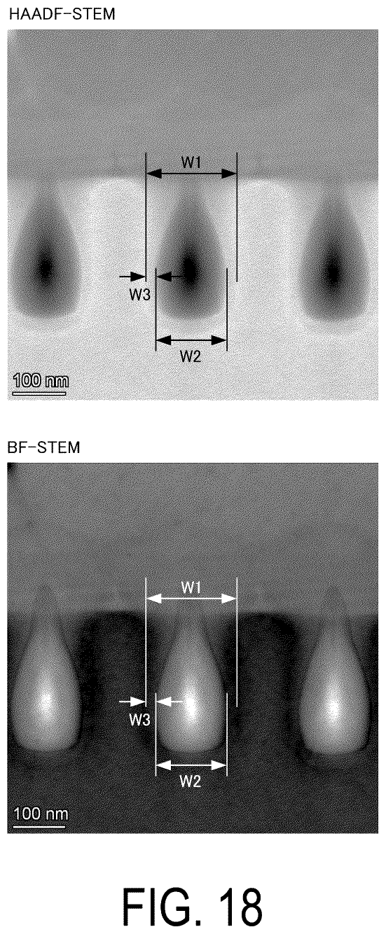

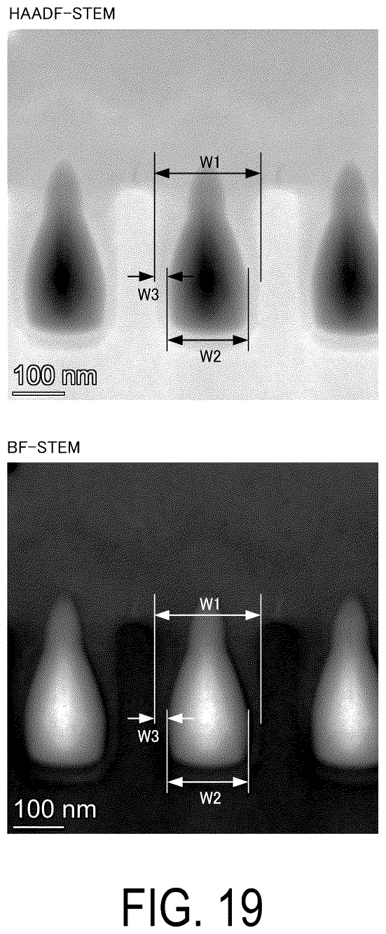

FIG. 17 shows an HAADF (High-Angle Annular Dark Field)-STEM image and a BF (Bright-Field)—STEM image of the first region. FIG. 18 shows HAADF-STEM and BF-STEM images of the second region. FIG. 19 shows HAADF-STEM and BF-STEM images of the third region.

As shown in FIG. 17, a void was observed in a hole in the first region. In the first region, a diameter W1 of the hole was 127 mm. A diameter W2 of the void was 91 mm. A pitch of the holes was 261 nm. A thickness W3 of the AlGaAs layer on a side surface of the hole was 18 nm. W3=(W1−W2)/2.

As shown in FIG. 18, a void was observed in a hole in the second region. In the second region, the diameter W1 of the hole was 164 mm. The diameter W2 of the void was 118 mm. The pitch of the holes was 264 nm. The thickness W3 was 23 nm.

As shown in FIG. 19, a void was observed in a hole in the third region. In the third region, the diameter W1 of the hole was 182 mm. The diameter W2 of the void was 133 mm. The pitch of the holes was 264 nm. The thickness W3 was 24.5 nm.

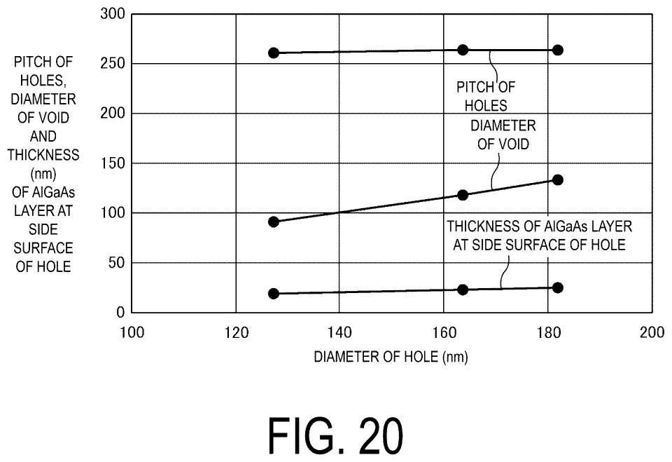

FIG. 20 is a graph showing a relationship among the diameter of the hole, the pitch of the holes, the diameter of the void, and the thickness of the AlGaAs layer on the side surface of the hole, in the first region, the second region, and the third region.

As shown in FIGS. 17 to 20, the thickness W3 of the AlGaAs layer on the side surface of the hole was increased as the diameter W1 of the hole was increased. Therefore, it was found that a shadow effect can be exhibited by the crystal growth of the AlGaAs layer shown in the experimental example. There was little change in the pitch of the holes in the first region, the second region, and the third region.

The embodiments and modified examples described above are examples and are not intended as limiting. For example, each embodiment and each modified example can also be combined together as appropriate.

The present disclosure includes configurations that are substantially identical to the configurations described in the embodiments, for example, configurations with identical functions, methods and results, or with identical objects and effects. Also, the present disclosure includes configurations obtained by replacing non-essential portions of the configurations described in the embodiments. For example, a material containing GaN may be crystallized at a GaN substrate to form the first semiconductor layer 20, the light-emitting layer 30, the first layer 42, the second layer 44, and the second semiconductor layer 50 made of the material containing GaN.

In addition, the present disclosure includes configurations having the same operations and effects or can achieve the same objects as the configurations described in the embodiments. Further, the present disclosure includes configurations obtained by adding known techniques to the configurations described in the embodiments.

The following content is derived from the embodiments and modified examples described above.

One aspect of a method for manufacturing a photonic crystal includes
forming a first layer,
forming a first hole and a second hole at the first layer,
crystal-growing a second layer at the first hole and the second hole, to form, at the first hole, a first low refractive index portion having a refractive index lower than that of the first layer, and form a second low refractive index portion having a refractive index lower than that of the first layer at the second hole, wherein
during formation of the first hole and the second hole,
the first hole and the second hole are formed such that a diameter of the first hole is greater than a diameter of the second hole, and
during formation of the first low refractive index portion and the second low refractive index portion,
the second layer is crystal-grown such that a difference between the diameter of the first hole and a diameter of the first low refractive index portion is greater than a difference between the diameter of the second hole and a diameter of the second low refractive index portion.

According to this method for manufacturing the photonic crystal, a photonic crystal capable of exhibiting a stable optical confinement effect can be manufactured.

In one aspect of the method for manufacturing the photonic crystal,
a refractive index of the first layer and a refractive index of the second layer may be different from each other.

According to this method for manufacturing the photonic crystal, it is easy to adjust a refractive index of the photonic crystal.

In one aspect of the method for manufacturing the photonic crystal, the second layer may be crystal-grown by an MOCVD method.

According to this method for manufacturing the photonic crystal, a shadow effect can be exhibited in the crystal growth of the second layer.

In one aspect of the method for manufacturing the photonic crystal,
a growth temperature of the second layer may be from 550° C. to 650° C.

According to this method for manufacturing the photonic crystal, the shadow effect can be exhibited in the crystal growth of the second layer.

In one aspect of the method for manufacturing the photonic crystal,
the second layer is a group III-V semiconductor layer, and
in the crystal growth of the second layer, a ratio of a flow rate of a second gas for supplying a group V element to a flow rate of a first gas for supplying a group III element may be from 10 to 30.

According to this method for manufacturing the photonic crystal, the shadow effect can be exhibited in the crystal growth of the second layer.

In one aspect of the method for manufacturing the photonic crystal,
the first low refractive index portion and the second low refractive index portion may be void.

According to this method for manufacturing the photonic crystal, a refractive index of the first low refractive index portion and a refractive index of the second low refractive index portion can be lowered.

In one aspect of the method for manufacturing the photonic crystal,
in the crystal growth of the second layer, an upside of the first hole and the second hole is closed by the second layer, so that the first gas and the second gas are no more supplied to the first hole and the second hole, and the void is formed, and
the upside of the first hole may be closed later than the upside of the second hole.

According to this method for manufacturing the photonic crystal, a difference between the diameter of the first hole and the diameter of the first low refractive index portion can be made greater than a difference between the diameter of the second hole and the diameter of the second low refractive index portion.

One aspect of a method for manufacturing a light-emitting device includes
the one aspect of the method for manufacturing the photonic crystal.

According to the method for manufacturing the light-emitting device, it is possible to reduce variations in a threshold current density.

What is claimed is:

1. A method for manufacturing a photonic crystal, comprising:
forming a first layer;
forming a first hole and a second hole at the first layer;
crystal-growing a second layer at the first hole and the second hole, to form, at the first hole, a first low refractive index portion having a refractive index lower than that of the first layer, and form, at the second hole, a second low refractive index portion having a refractive index lower than that of the first layer, wherein
during formation of the first hole and the second hole,
the first hole and the second hole are formed such that a diameter of the first hole is greater than a diameter of the second hole, and
during formation of the first low refractive index portion and the second low refractive index portion,
the second layer is crystal-grown such that a difference between the diameter of the first hole and a diameter of the first low refractive index portion is greater than a difference between the diameter of the second hole and a diameter of the second low refractive index portion.

2. The method for manufacturing the photonic crystal according to claim 1, wherein
the refractive index of the first layer and a refractive index of the second layer are different from each other.

3. The method for manufacturing the photonic crystal according to claim 1, wherein
the second layer is crystal-grown by an MOCVD method.

4. The method for manufacturing the photonic crystal according to claim 3, wherein
a growth temperature of the second layer is from 550° C. to 650° C.

5. The method for manufacturing the photonic crystal according to claim 4, wherein
the second layer is a group III-V semiconductor layer, and
in the crystal growth of the second layer, a ratio of a flow rate of a second gas for supplying a group V element to a flow rate of a first gas for supplying a group III element is from 10 to 30.

6. The method for manufacturing the photonic crystal according to claim 5, wherein
the first low refractive index portion and the second low refractive index portion are void.

7. The method for manufacturing the photonic crystal according to claim 6, wherein
in the crystal growth of the second layer, an upside of the first hole and the second hole is closed by the second layer, so that the first gas and the second gas are no more supplied to the first hole and the second hole, and thus the void is formed, and
the upside of the first hole is closed later than the upside of the second hole.

8. A method for manufacturing a light-emitting device comprising the method for manufacturing the photonic crystal according to claim 1.
